(19) United States
(12) Patent Application Publication
(10) Pub. No.: US 2025/0233444 A1
(43) Pub. Date: Jul. 17, 2025

(54) UNINTERRUPTIBLE POWER MODULES FOR UNINTERRUPTIBLE POWER SUPPLIES (UPSs) AND RELATED UNINTERRUPTIBLE POWER MODULES

(71) Applicant: Eaton Intelligent Power Limited, Dublin 4 (IE)

(72) Inventors: Lei Cao, Shenzhen (CN); Yulong Hao, Shenzhen (CN); Yunmei Wu, Shenzhen (CN); Zhimin Shen, Shenzhen (CN); Ping Zhang, Shenzhen (CN)

(21) Appl. No.: 19/014,493

(22) Filed: Jan. 9, 2025

(30) Foreign Application Priority Data
Jan. 11, 2024 (CN) 202420079552.5

(51) Int. Cl. H02J 9/06; H05K 7/14; H05K 7/20

(52) U.S. Cl. CPC H02J 9/06; H05K 7/1432; H05K 7/209; H05K 7/20909

(57) ABSTRACT

Uninterruptible power modules for use with uninterruptible power supplies are provides. The uninterruptible power modules include a rectification module, an inverter module and a fan module which are detachably assembled together. The rectification module includes a first housing; a first electrical network, mounted to the first housing, the first electrical network is configured to be selectively connected to a main power supply or current supplied by a standby power supply and convert the current provided by a main power supply or a standby power supply into DC current. The inverter module includes a second housing, detachably connected to the first housing; a second electrical network, which is mounted to the second housing and connected to the first electrical network. The second electrical network is converts DC into AC power. The uninterruptible power module further includes a transfer switch that controls the first electrical network from being connected with the main power supply to being connected with the standby power supply.

### CROSS-REFERENCE TO PRIORITY APPLICATION

This application claims priority to Chinese Patent Application No. 202420079552.5, filed Jan. 11, 2024, the content of which is hereby incorporated herein by reference in its entirety.

### TECHNICAL FIELD

This disclosure relates generally to power supply devices and, more particularly, to uninterruptible power modules and uninterruptible power supplies (UPSs).

### BACKGROUND

An uninterruptible power supply (UPS) is a device for uninterruptible providing a standby AC power supply to power load devices in order to maintain the normal operation of the power load devices in the case of an abnormal power grid. Normally, the uninterruptible power supply is used to maintain the uninterruptible operation of key devices or precision instruments, such as computers or exchangers, to prevent computer data loss, telephone communication network interruption, or loss of instrument control. The data central power supply system is a typical UPS system, in which a municipal main power supply can provide three-phase alternating current (AC) power to one or more UPS systems supporting critical data central loads. When the municipal main power supply is cut off, the data central UPS can undertake the function of supplying power to the key power load devices.

It is known that a large or medium UPS power supply system with modularized construction, which comprises a system cabinet, an uninterruptible power module (UPM), a communication module, a display module and so on. In such a UPS system, each UPM is about 50 kilograms (kg) and has a large volume, to boost many difficulties of the installation and removal work.

Therefore, there is a certain demand in the industry for improving the UPM structure to reduce the installation and maintenance difficulties.

### SUMMARY

Embodiments discussed in the present disclosure provide uninterruptible power modules, which address the problems discussed above. The present disclosure further discusses uninterruptible power supplies, which include the improved uninterruptible power module discussed herein.

According some embodiments, an uninterruptible power module for an uninterruptible power supply is provided, an uninterruptible power module comprises a rectification module, an inverter module and a fan module which are detachably assembled together, wherein the rectification module comprises: a first housing; a first electrical network, which is mounted to the first housing, the first electrical network is configured to be selectively connected to a main power supply or a standby power supply and to convert a current supplied by a main power supply or a current supplied by a standby power supply to a direct current; The inverter module comprises: a second housing, which is detachably connected with the first housing; a second electrical network, which is mounted to the second housing and connected to the first electrical network, the second electrical network is configured to convert a direct current into an alternating current; wherein the uninterruptible power module further comprises a transfer switch capable of controlling the first electrical network to be converted from being connected with the main power supply into being connected with the standby power supply.

The uninterruptible power module (UPM) provided according to some embodiments is suitable for constructing a large-scaled or medium-sized modularized UPS power supply system and is easy to assemble and maintain. The uninterruptible power module carries out partial module design for the main functional devices such as rectification module, inverter module, fan module and so on, and constructs a rectification module, an inversion module and a fan module which can be separated from each other, each module realizes corresponding function. In this way, no matter if the uninterruptible power module is installed in the system cabinet or removed from the system cabinet for maintenance or replacement, it can be detached and assembled according to the module area, and it can be finished by only one person, which saves time and labor. Each module adopts standard interfaces, when malfunction occurs on one module, it can be replaced by another module with the same function without discarding the whole uninterruptible power module.

In some embodiments, one of the first housing and the second housing is provided with a guide piece, and the other is provided with a sliding piece, the sliding piece is configured to be movable along the guide piece to assemble the rectification module and the inverter module together or to detach the assembly of both.

In some embodiments, the sliding piece is configured with a slideway, and the guide piece can be embedded in the slideway of the sliding piece to allow the sliding piece to move along the guide piece.

In some embodiments, a pair of sliding pieces are spaced apart, they are opposite to each other to form a slideway, and a pair of guide piece can be respectively embedded in the slideway of the sliding piece on the corresponding side.

In some embodiments, the guide piece comprises: a first guide plate section, which extends toward the other guide piece; a second guide plate section, which is angularly connected to the extension end of the first guide plate section; and a third guide plate section, which is angularly connected to an end of the second guide plate section away from the first guide plate section and extends away from the other guide piece.

In some embodiments, the sliding piece comprises: a first sliding plate section which extends toward the other sliding piece; a second sliding plate section, which is angularly connected to the extension end of the first sliding plate section to form the slideway.

In some embodiments, the first housing and the second housing are disposed opposite each other and define a receiving space for receiving the first electrical network and the second electrical network.

In some embodiments, the fan module comprises: an end plate, which is detachably connected with the first housing and the second housing and forms a housing of the uninterruptible power module together with the first housing and the second housing, wherein the end plate is provided with a cooling hole; a fan, which is mounted on the end plate corresponding to the cooling hole; wherein the transfer switch is mounted on the end plate.

In some embodiments, the first electrical network and/or the second electrical network comprise(s) a unit assembled by at least one SiC module and a heat sink, the unit is mounted to a printed circuit board at a side of the SiC module away from the heat sink, wherein the heat sink comprises a fin and a temperature uniformity plate located on the end part of the fin, the SiC module is mounted to the temperature uniformity plate.

According to further embodiments, an uninterruptible power supply is provided, comprises: a system cabinet; and an uninterruptible power module, which is arranged in the system cabinet; the uninterruptible power module is said uninterruptible power module.

Other features and advantages of the present utility model will be obvious to those skilled in the art after reading the present application, and the other part will be described in the following detailed description with reference to the accompanied figures.

### BRIEF DESCRIPTION OF FIGURES

Hereinafter, the embodiments of present disclosure are described in detail with reference to the accompanied figures, in which:

FIG. 1 is an angular schematic view of an uninterruptible power module (UPM) according to some embodiments of present disclosure.

FIG. 2 is an angular schematic view of the UPM according to some embodiments of present disclosure.

FIG. 3 is an exploded view of a UPM according to some embodiments of present disclosure.

FIG. 4 is a schematic view of a rectification module according to some embodiments of present disclosure.

FIG. 5 is an enlarged view at A of FIG. 4.

FIG. 6 is a schematic view of an inverter module according to some embodiments of present disclosure.

FIG. 7 is an enlarged view at B of FIG. 6.

FIG. 8 is a schematic view of assembling silicon carbide (SiC) module, the heat sink and the printed circuit board (PCB) together according to some embodiments of present disclosure.

FIG. 9 is an exploded view of the devices shown in FIG. 8.

FIG. 10 is an enlarged view at C of FIG. 9.

FIG. 11 is an exploded view of a fan module according to an embodiment of present disclosure.

FIG. 12 is a sectional view of the UPM according to some embodiments of present disclosure.

FIG. 13 is an enlarged view at D of FIG. 12.

FIG. 14 is an enlarged view at E of FIG. 12.

FIG. 15 is a partial schematic view of an uninterruptible power supply (UPS) according to some embodiments of present disclosure.

### DETAILED DESCRIPTION

With reference to the accompanied figures, the exemplary embodiments of the uninterruptible power module and uninterruptible power supply disclosed herein will be specified in detail. Although the figures are provided to present some embodiments of present disclosure, the figures need not be drawn according to the dimensions of the specific embodiments, and certain features may be magnified, removed or otherwise partially sectioned to better show and explain present disclosure herein. Positions of partial members in the accompanied figures can be adjusted according to the actual demand without influencing the technical effect. The phrase “in the accompanied figures” or the similar words appearing in the specification does not need to refer to all the accompanied figures or examples.

Certain directional terms, such as “inner”, “outer”, “upper”, “lower” and other directional terms, which are used hereinafter to describe the figures, will be understood to have their normal meaning and refer to those directions referred to in the normal view of the accompanied figures. Unless otherwise indicated, the directional terms described in this specification are substantially in accordance with the conventional direction understood by those skilled in the art.

The terms “first”, “first”, “second”, “second” and similar terms as used herein are not intended to indicate any order, number, or importance in this context, but are intended to distinguish a component from other components.

Present disclosure provides an uninterruptible power module suitable for large-scale or medium-sized modularized/tower type UPS, especially 125 kilowatt (kW) uninterruptible power module.

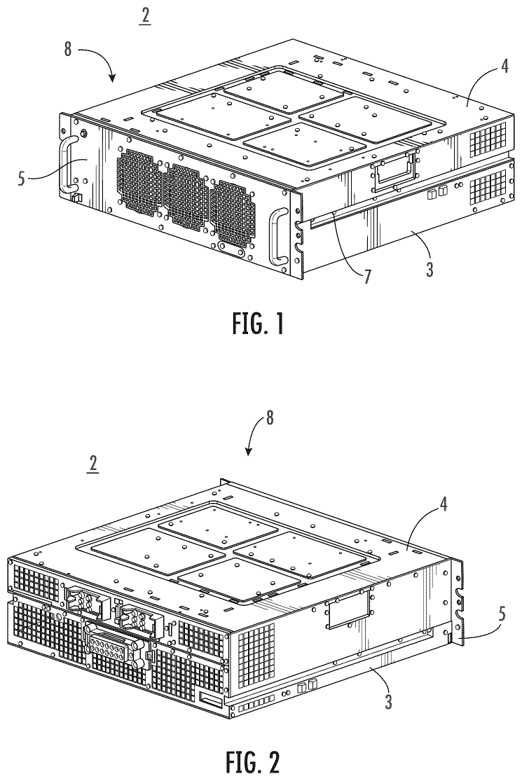

Referring to FIGS. 1 to 3, a schematic view of an uninterruptible power module 2 is shown, which comprises a housing 8 in which each device implementing the function of the uninterruptible power module are enclosed. The housing 8 is a three-dimensional body made of a solid material for protection of each device. The input port 37 may be accessed from the exterior of the housing 8 such that the uninterruptible power module 2 may be selectively connected to a primary power supply (e.g., a three-phase AC power supply, such as municipal main power supply) or a standby power supply (e.g., a DC battery). The output port 47 can also be accessed from the exterior of the housing 8 so that the power load can be connected to the uninterruptible power module 2 at the output port 47. The uninterruptible power module 2 generates an alternating current power for the power load based on the electric power from the main power supply or the standby power supply.

The uninterruptible power module 2 can be divided into a rectification module 3, an inverter module 4 and a fan module 5 according to the function area. These modules are detachably connected with each other. Thereby, each module can be operated one by one when the uninterruptible power module is arranged in the UPS system cabinet or the uninterruptible power module is removed from the UPS system cabinet, which can be finished by only one person. As used herein, terms “detachably” or “detachable” mean that the components connected together may be separated from each other, and that the separated components still have a configuration and function consistent with the initial state before disconnection, such configuration and function will not be affected by separate operations.

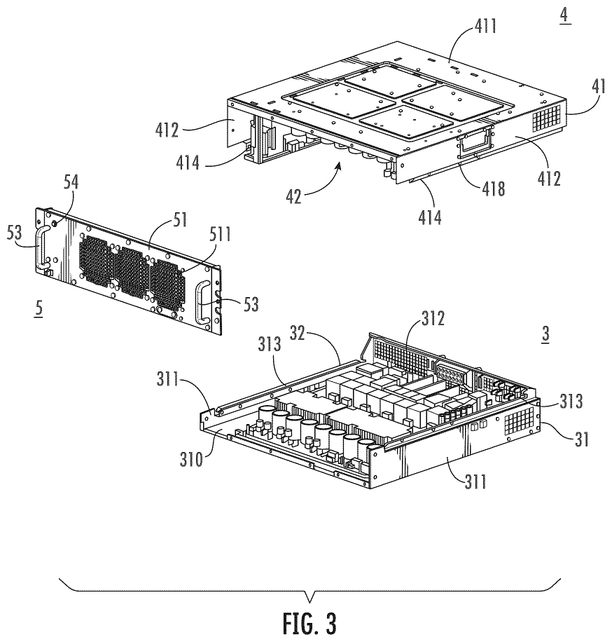

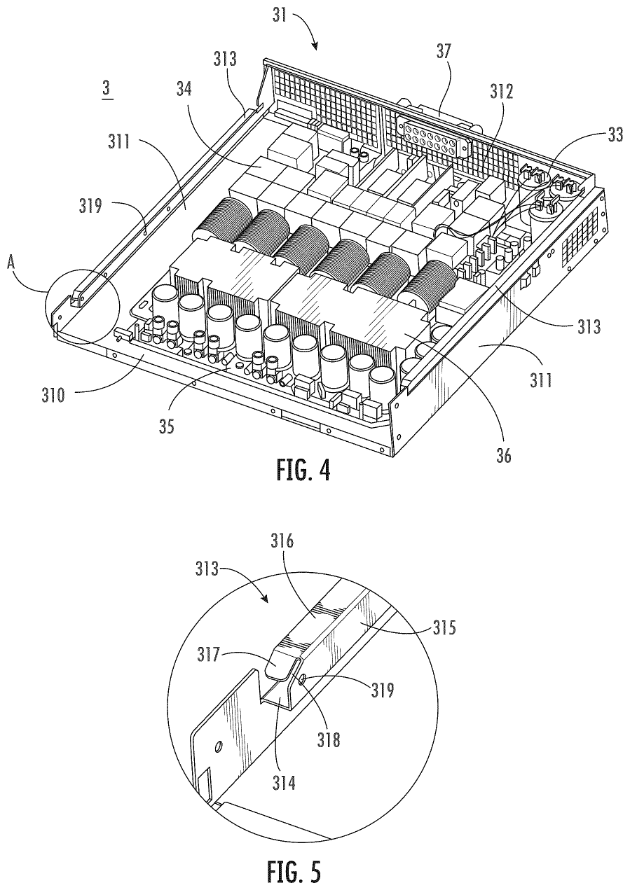

As shown in FIGS. 3 and 4, the rectification module 3 comprises a first housing 31 and a first electrical network 32 (or “first circuit”) mounted to the first housing 31. The first electrical network 32 is configured to be selectively connected to the main power supply (primary) or standby power supply (secondary) via the input port 37 and to convert the current supplied by the main power supply or the current supplied by the standby power supply to a direct current (DC). The selective connection may be implemented, for example, by a transfer switch, as will be described in more detail below.

The first housing 31 comprises a first wall 310, which can be viewed as the bottom wall of the housing 8 of the uninterruptible power module 2, and two first side walls 311 connected to opposite ends of the first wall 310, and a first end wall 312 connecting the first wall 310 and the two first side walls 311. The first end wall 312 may be located at the rear end of the uninterruptible power module 2. The input port 37 is mounted to the first end wall 312. FIGS. 2 and 4 show an input port 37, but it will be understood by those skilled in the art that there may be two input ports 37, one of which may be used for connection to a primary power supply and the other may be used for connection to a standby power supply. Under the control of a relay, the two input ports 37 are electrically conducted separately or simultaneously.

All devices of the first electrical network 32 are mounted to the first housing 31. As shown in FIG. 4, the first electrical network 33 may include a first capacitor 33, a first I/O circuit board 34, a first power board 35, and a control circuit board and so on (not shown). The input port 37 is connected to a first I/O circuit board 34, wherein the current path on the first I/O circuit board 34 runs firstly from a fuse to the relay and then runs from the relay to an inductor. The first I/O circuit board 34 is connected to a first power board 35, wherein the current path on the first power board 35 runs from the semiconductor module to a bus (BUS) capacitor. The first capacitor 33 may be, for example, an oil capacitor (or referred to as an “oil-immersed capacitor”). The oil capacitor and the inductor on the first I/O circuit board 34 form a separate current loop, which is an inductive filter loop. The mounting of the devices in the first electrical network 32 on the first housing 31 is adapted such that the two first side walls 311 of the first housing 31 may have different heights. Of course, two first side walls 311 with the same height are also feasible.

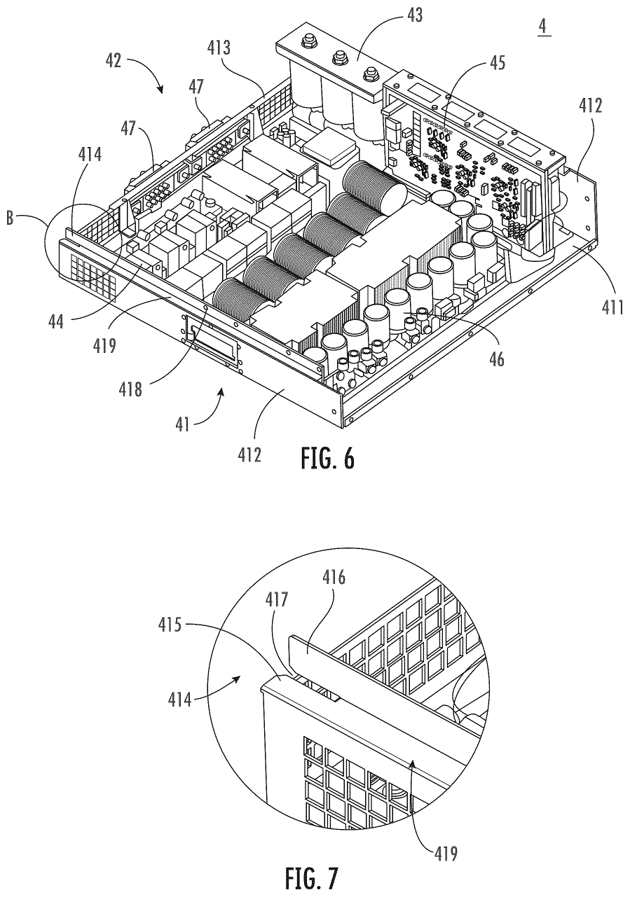

FIG. 3 and FIG. 6 show the inverter module 4. The inverter module 4 comprises a second housing 41 and a second electrical network 42 (or “second circuit”) mounted to the second housing 41. The second electrical network 42 is connected to the first electrical network 32 and is configured to convert DC to AC and provide AC electrical power to the power load via the output port 47.

The second housing 41 comprises a second wall 411, which can be viewed as the top wall of the housing 8 of the uninterruptible power module 2, and two second side walls 412 connected to opposite ends of the second wall 411, and comprises a second end wall 413 connecting the second wall 411 and the two second side walls 412. The second end wall 413 may be located at the rear end of the uninterruptible power module 2. The output port 47 is mounted to the second end wall 413. FIG. 2 and FIG. 6 show two output ports 47, but it will be understood by those skilled in the art that the number of output ports 47 may be one or more than two.

All devices of the second electrical network 42 are mounted to the second housing 41. As shown in FIG. 6, the second electrical network 42 comprises a second capacitor 43, a second I/O circuit board 44, a power supply board (SPS) and a control board (CNTL) 45, and a second power board 46. The second power plate 46 is connected to the first power plate 35, wherein the current path on the second power plate 46 runs from the bus capacitor to the semiconductor module. The second power board 46 is connected to a second I/O circuit board 44, wherein the current path on the second I/O circuit board 44 runs from an inductor to a relay, then from a relay to a fuse. The second I/O circuit board 44 is connected to the output port 47. The second capacitor 43 may be an oil capacitor (or referred to as an “oil-immersed capacitor”). The oil capacitor and the inductor on the second I/O circuit board 44 form a separate current loop, which is an inductive filter loop. The two second side walls 412 of the second housing 41 may be of different heights in order to adapt the mounting of the devices in the second electrical network 42 on the second housing 41. Of course, two second side walls 412 with the same height are also feasible.

According to the shown embodiment, in the assembled uninterruptible power module 2, the inverter module 4 is overlapped with the rectification module 3, wherein the second wall 411 of the second housing 4 is opposite to the first wall 310 of the first housing 311 up and down, the first electrical network 32 is arranged on the bottom wall of the housing 8, and the second electrical network 42 is arranged on the top wall of the housing 8. The two first side walls 311 of the first housing 311 correspond to the two second side walls 412 of the second housing 4 respectively, and the first end wall 312 of the first housing 311 corresponds to the second end wall 413 of the second housing 4. The first end wall 312 and the second end wall 413 together form the rear wall of the housing 8. In the case where the two first side walls 311 have different heights and the two second side walls 412 have different heights, the shorter one of the second side walls 412 is aligned with the higher one of the first side walls 311 and the higher one of the second side walls 412 is aligned with the shorter one of the first side walls 311.

In order to facilitate the assembly or maintenance of the rectification module 3 and the inverter module 4, a guide connection structure may be provided between the first housing 31 and the second housing 41. The first housing 31 and the second housing 41 are connected together or detached in a simple and easy-to-operate manner by guiding and aligning the guide connection structure.

The guide connection structure may, in one embodiment, be a guide piece mounted on one of the first housing 31 and the second housing 41 and a sliding piece mounted on another one of the first housing 31 and the second housing 41, and the sliding piece may move in a guide direction of the guide piece.

In the shown embodiment, the first housing 31 may be provided with a guide piece 313 and the second housing 41 may be provided with a sliding piece 414. As shown in FIGS. 4 and 5, in the first housing 31, an end of each of the first side walls 311 away from the first wall 310 is provided with a guide piece 313 configured as a guide rail extending between the front and rear ends of the uninterruptible power module 2 along the length of the first side wall 311. The guide piece 313 may be formed, for example, by bending the plate of the housing 8. Specifically, the first guide plate section 314 of the guide piece 313 extends from the corresponding first side wall 311 toward the guide piece 313, and the second guide plate section 315 of the guide piece 313 is connected to the extension end of the first guide plate section 314 in an angle (e.g., 90 degrees). The third guide plate section 316 of the guide piece 313 extends from the end of the second guide plate section 315 away from the first guide plate section 314 to the other side of the guide piece 313, and the second guide plate section 315 and the third guide plate section 316 form an included angle (e.g., 90 degrees). Therefore, the guide piece 313 is configured to have a transverse U-shaped or [symbol] -shaped cross section. The guide piece 313 is simple in structure, which can be formed by bending the material of the first housing 31 and has high strength.

As shown in FIG. 5, in one embodiment, at one end of the guide piece 313 away from the first end wall 312, the third guide plate section 316 is formed with an inclined section 317 bending toward the first guide plate section 314, and the second guide plate section 315 has an inclined surface corresponding to the inclined section 317, and a first slit 318 is formed between the inclined section 317 and the inclined surface.

As shown in FIGS. 6 and 7, in the second housing 41, the end of each second side wall 412 away from the second wall 411 is provided with a sliding piece 414 extending between the front and rear ends of the uninterruptible power module 2 along the length of the second side wall 412. The sliding piece 414 may be formed, for example, by bending the plate of the housing 8. Specifically, the first sliding plate segment 415 of the sliding piece 414 extends from the corresponding second side wall 412 toward the sliding piece 414 on the other side, and the second sliding plate segment 416 of the sliding piece 414 is connected to the extension end of the first sliding plate segment 415 in an angle (e.g., 90 degrees). Thus, the sliding piece 414 can be configured with an L-shaped cross-section, whereby each sliding piece 414 forms a slideway 419 away from the other sliding piece 414, the slideway 419 extends between the front and rear ends of the uninterruptible power module 2 along the length of the second side wall 412. The sliding piece 414 is simple in structure and can be formed by bending the material of the second housing 41.

As shown in FIG. 6, in one embodiment, at an end of the sliding piece 414 adjacent to the second end wall 413, a second slit 417 is defined between the first sliding plate segment 415 and the second sliding plate segment 416, the second slit 417 extends a small distance along the length of the sliding piece 414.

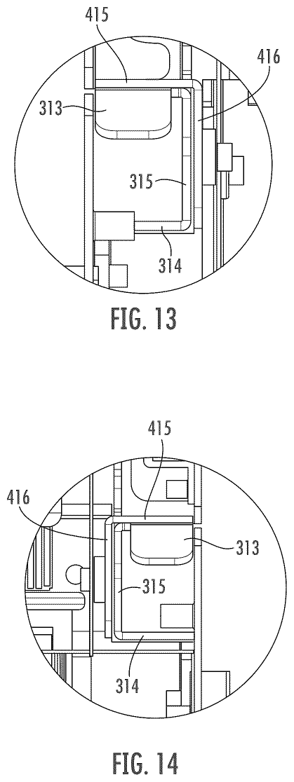

When the rectification module 3 and the inverter module 4 need to be assembled, it only needs to align the sliding piece 414 on the second side wall 412 to the corresponding guide piece 313 on the first side wall 311, so that the guide piece 313 is embedded in the slideway 419 of the sliding piece 414, then, the inverter module 4 is pushed to move the sliding piece 414 along the guide piece 313. Conversely, the inverter module 4 can be pulled to be detached from the rectification module 3. As shown in FIGS. 12 to 14, during movement, the second sliding plate segment 416 of the sliding piece 414 abuts against the inner side of the second guide plate segment 315 of the guide piece 313 facing the other side of the guide piece 313, and the first slide plate segment 415 of the sliding piece 414 is supported by the third guide plate segment 316 of the guide piece 313, so that the weight of the inverter module 4 is not required to be borne by the operator either during assembly or disassembly.

Of course, any suitable configuration may be used to form the guide piece 313 and the sliding piece 414 as long as the guide piece is capable of guiding the direction of movement of the sliding piece and defining the trajectory of movement of the sliding piece. In addition, in an alternative embodiment, the guide piece may also be disposed on the second housing and the sliding piece may be disposed on the first housing.

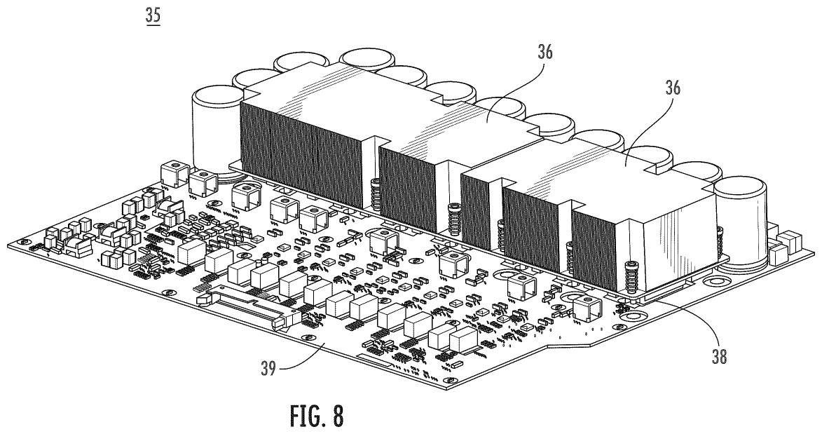

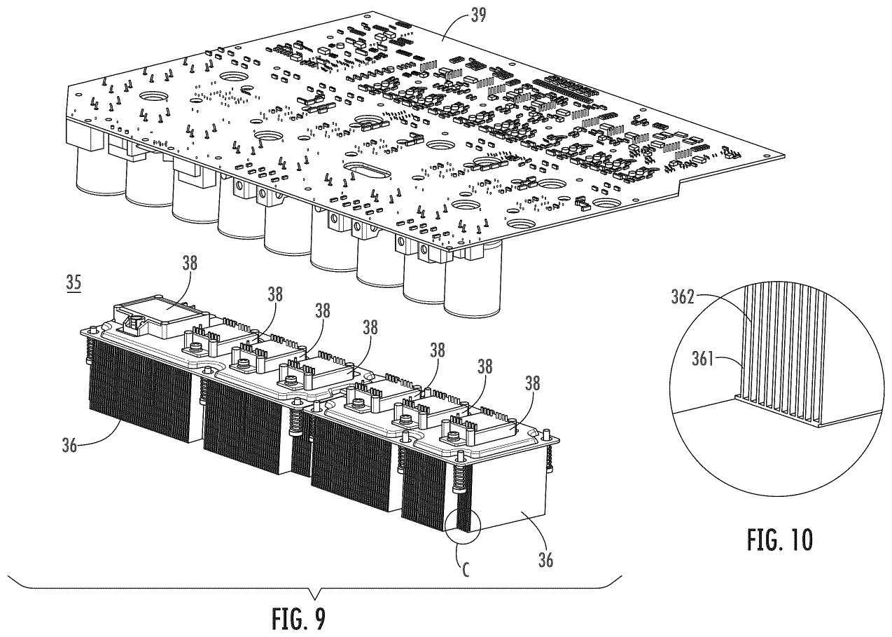

In the uninterruptible power module 2 provided herein, the first electrical network 32 may include one or more electronic devices made of semiconductor material. For example, as shown in FIGS. 8 and 9, the first electrical network 32 may be provided with a SiC module 38 on the first power plate 35. The SiC module 38 may have a small volume to provide greater power. The heat sink 36 is matched with the SiC module 38. As shown in FIG. 10, the heat sink 36 comprises a plurality of fins 361 arranged side by side and substantially parallel to each other, and a temperature uniformity plate located at the end of the fin 361, wherein the temperature uniformity plate is located above the fin 361 in embodiments shown in the figure, and the SiC module 38 is locked to the temperature uniformity plate, for example, by screws. These fins 361 are connected to each other at upper and lower ends, while the portions between the upper and lower ends are spaced apart from each other so as to define a heat release channel 362 between two adjacent fins 361. The temperature uniformity plate has an inner cavity in which a material having good thermal conductivity can be arranged as desired, such as at least one of the following materials: copper net, copper powder, copper support and a small amount of water. By coupling the temperature uniformity plate to the semiconductor module, the heat generated by the semiconductor module can be quickly conducted and quickly dissipated through the fin 361, so as to ensure the stable operation of the semiconductor device. Each heat sink 36 may provide heat release for a plurality of SiC modules 38. These SiC modules 38 are assembled with the corresponding heat sinks 36 together via connectors (e.g., bolts or screws) to form an electronic unit, which is then mounted to the PCB 39 via connectors from the side of the SiC modules 38 away from the heat sinks 36.

Similar to the first electrical network 32, the second electrical network 42 may also include one or more electronic devices of semiconductor material. For example, similar to the first power plate 35, a unit composed of a SiC module and a heat sink can also be mounted on the second power plate 46.

The first housing 31 and the second housing 41 can be connected by a detachable connecting member 7 (such as a bolt or a screw) after being assembled. For this purpose, the first housing 31 may be provided with a plurality of first holes 319 along length of the guide piece 313, and a plurality of second holes 418 along length of the slide 414. After the inverter module 4 is assembled with the rectification module 3 together, the first hole 319 is aligned with the second hole 418 one by one to allow the connection member 7 to pass through. For the purpose of facilitating the disassembly of the rectification module 3 and the inverter module 4 from the system cabinet of the UPS, a plurality of first holes 319 and a plurality of second holes 419 can be arranged only within the ⅔ length of the housing from the front end of the uninterruptible power module 2.

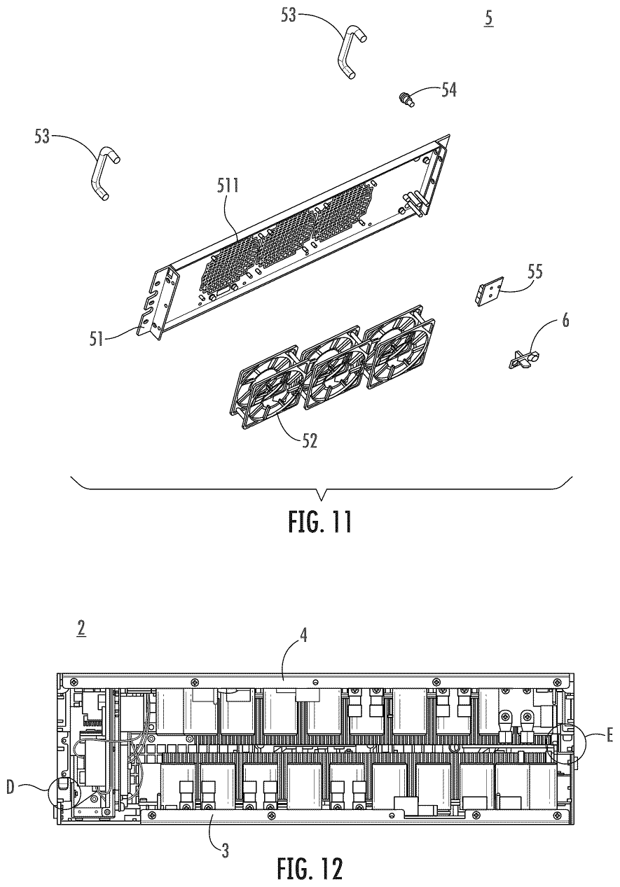

The fan module 5 is detachably connected with the rectification module 3 and the inverter module 4. FIG. 11 shows a fan module 5, which comprises an end plate 51, which may be viewed as the front panel of the uninterruptible power module 2, the end plate 51 may be located at the front end of the uninterruptible power module 2. The end plate 51 is formed with a group of cooling holes 511, wherein at least one fan 52 can be mounted corresponding to each group of cooling holes 511. Of course, the cooling holes can be arranged in an evenly spaced array without grouping. After the rectification module 3 and the inverter module 4 are assembled by the guide piece 313 and the sliding piece 414 in an up-down alignment, the end plate 51 can be connected to the first housing 31 through a detachable connecting member (such as a bolt or a screw) at one side of the first housing 31 far way from the first end wall 312. Similarly, the end plate 51 may be connected to the second housing 41 via a detachable connection (such as a bolt or a screw) on the side of the second housing 41 away from the second end wall 413. For this purpose, the end plate 51, the first housing 31 and the second housing 41 together form the housing 8 of the uninterruptible power module 2.

In the shown embodiment, the transfer switch 54 for controlling the uninterruptible power module 2 to be connected to the main power supply or the standby power supply is mounted to the end plate 51. The transfer switch 54 may be configured as a press button, push button or rotary knob that pass through the end plate 51 with one end located in the interior space of the housing 8 and connected to the power supply plate and the control plate 45 and with the other end extending out of the housing 8 for operation.

The micro-switch plate (LED plate) 55 is mounted on one side of the end plate 51 facing the inner space of the housing 8 and is connected to the power supply plate and the control plate 45. The micro-switch plate 55 is used for supplying power to the fan 52.

In order to facilitate installation and maintenance, a handle 53 is mounted on the side of the end plate 51 away from the inner space of the housing 8.

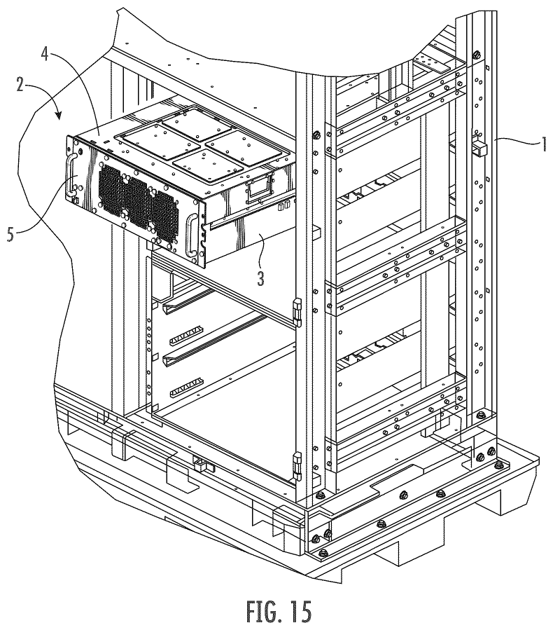

FIG. 15 shows an uninterruptible power module 2 mounted to a system cabinet 1 of a UPS, the uninterruptible power module 2 being shown in a state withdrawn from the system cabinet 1 but not completely removed from the system cabinet 1. The modularized uninterruptible power module 2 described above is particularly advantageous in this case because each module can be removed one by one, without the need for the operator to always bear the tens of kilograms weight of the entire uninterruptible power module 2.

In one embodiment, when it is necessary to remove the uninterruptible power module 2 from the system cabinet 1, as shown in FIG. 15, the following operations are required:

The uninterruptible power module 2 is drawn out from the system cabinet 1 in a substantially horizontal direction, but without the need for the entire removal, but is drawn out by a length of approximately ⅔-¾ of the length of the housing 8 from the front end. In this extraction process, the weight of the uninterruptible power module 2 is almost entirely borne by the system cabinet 1.

The connector between the end plate 51 of the fan module 5 and the first housing 31 and the second housing 41 are detached to remove the fan module 5. The fan module 5 generally has a weight of 1-3 kilograms (kg).

A small amount of cable is removed from the front end of the uninterruptible power module 2.

The connector 7 between the first housing 31 and the second housing 41 is detached.

The inverter module 4 above is pulled out along the guide piece 313, and the inverter module 4 is removed from the system cabinet 1. The weight of the inverter module 4 is generally 20-25 kg.

The remaining rectification module 3 is pulled out, and the rectification module 3 is removed from the system cabinet 1. The rectification module 3 generally has a weight of 20-30 kg.

The whole process of removing the uninterruptible power module 2 can be completed by an operator. The uninterruptible power module 2 is installed in the system cabinet 1, and can be installed in separate module areas one by one. In order to prevent the installed uninterruptible power module 2 from accidentally moving in the system cabinet 1, a locking structure can be installed between the housing 8 of the uninterruptible power module 2 and the system cabinet 1. For example, a locking member 6 may be mounted on the end plate 51 of the fan module 5. The uninterruptible power module 2 is fixed in the system cabinet 1 by the bayonet lock extending from the housing 8 by operating the locking member 6.

The uninterruptible power module provided herein can be applied to the module area flexibly. For example, two inversion modules and one fan module are assembled together to form an energy storage device applied to an energy storage system, and two rectification modules and one fan module are assembled together to form a power charging conversion device applied to a power charging pile of an electric vehicle.

It should be understood that although the present specification is described according to various embodiments, not each embodiment contains only one independent technical solution, the description way of the specification is only for the purpose of clarity, and those skilled in the art should take the specification as a whole. The technical solutions in the embodiments can also be suitably combined to form other embodiments that can be understood by those skilled in the art.

The foregoing is only illustrative embodiments of present disclosure and is not intended to limit the scope of present disclosure. Any equivalent change, modification and combination made by those skilled in the art without departing from the concept and principle of present disclosure shall fall within the scope of present disclosure.

What is claimed is:

1. An uninterruptible power module for use in uninterruptible power supplies comprising:
a rectification module, an inverter module and a fan module detachably assembled together;
wherein the rectification module comprises:
a first housing;
a first electrical network, mounted to the first housing, the first electrical network is configured to be selectively connected to a main power supply or a standby power supply and to convert a current supplied by a main power supply or a current supplied by a standby power supply into a direct current;
wherein the inverter module comprises:
a second housing detachably connected to the first housing;
a second electrical network mounted to the second housing and connected to the first electrical network, the second electrical network is configured to convert direct current into alternating current; and
wherein the uninterruptible power module further comprises a transfer switch that controls a switch of the first electrical network between being connected with the main power supply and being connected with the standby power supply.

2. The uninterruptible power module of claim 1, wherein one of the first housing and the second housing is provided with a guide piece, and a remaining one is provided with a sliding piece; and wherein the sliding piece is configured to be movable along the guide piece to assemble the rectification module and the inverter module together or to detach an assembly of both.

3. The uninterruptible power module of claim 2, wherein the sliding piece is configured with a slideway and wherein the guide piece is embedded in the slideway of the sliding piece to allow the sliding piece to move along the guide piece.

4. The uninterruptible power module of claim 3, wherein a pair of sliding pieces are spaced apart and are opposite to each other to form a slideway and wherein and a pair of guide pieces are respectively embedded in the slideway of the sliding piece at a corresponding side.

5. The uninterruptible power module of claim 4, wherein the pair of guide pieces comprises:
a first guide plate section which extends toward the remaining guide piece;
a second guide plate section angularly connected to an extension end of the first guide plate section; and
a third guide plate section angularly connected to an end of the second guide plate section being away from the first guide plate section and extending away from the remaining guide piece.

6. The uninterruptible power module of claim 4, wherein the sliding piece comprises:
a first sliding plate section extending toward a remaining sliding piece; and
a second sliding plate section angularly connected to an extension end of the first sliding plate section to form the slideway.

7. The uninterruptible power module of claim 6, wherein the first housing and the second housing are arranged oppositely and define a receiving space for receiving the first electrical network and the second electrical network.

8. The uninterruptible power module of claim 6, wherein the fan module comprises:
an end plate detachably connected with the first housing and the second housing and forming a housing of the uninterruptible power module together with the first housing and the second housing, wherein the end plate is provided with a cooling hole; and
a fan mounted on the end plate corresponding to the cooling hole, wherein the transfer switch is mounted on the end plate.

9. The uninterruptible power module of claim 8:
wherein the first electrical network and/or the second electrical network comprises a unit assembled by at least one silicon carbide (SiC) module and a heat sink;
wherein the unit is mounted to a printed circuit board at a side of the SiC module away from the heat sink; and
wherein the heat sink comprises a fin and a temperature uniformity plate located on an end of the fin, and the SiC module is mounted to the temperature uniformity plate.

10. An uninterruptible power supply comprising:
a system cabinet; and
an uninterruptible power module arranged in the system cabinet, wherein, the uninterruptible power module is the uninterruptible power module of claim 1.
